(19) United States
(12) Patent Application Publication
(10) Pub. No.: US 2016/0149162 A1
(43) Pub. Date: May 26, 2016

(54) OPTOELECTRONIC COMPONENT, METHOD FOR PRODUCING AN OPTOELECTRONIC COMPONENT, AND MIRROR DEVICE

(71) Applicant: OSRAM OLED GMBH, Regensburg (DE)

(72) Inventors: Carola Diez, Regensburg (DE); Karsten Diekmann, Rattenberg (DE)

(21) Appl. No.: 14/900,184

(22) PCT Filed: Jun. 17, 2014
(86) PCT No.: PCT/EP2014/062708

§ 371 Date: Dec. 21, 2015

(30) Foreign Application Priority Data
Jun. 21, 2013 (DE) 10 2013 106 502.3

(51) Int. Cl. H01L 51/52; H01L 51/56; H01L 27/32

(52) U.S. Cl. CPC H01L 51/5271; H01L 27/3239; H01L 51/5206; H01L 51/5221; H01L 51/56

(57) ABSTRACT

Various embodiments may relate to an optoelectronic component, including a carrier, which is formed in a transparent fashion, an optoelectronic layer structure including a first electrode, which is formed above the carrier and which is formed in a transparent fashion, an optically functional layer structure, which is formed above the first electrode, and a second electrode, which is formed above the optically functional layer structure, wherein a mirror region is formed on a side of the optically functional layer structure facing away from the carrier, the mirror region being formed in a specularly reflective fashion as viewed at least from the carrier, and an intermediate layer, which is formed between the carrier and the mirror region and which has an optical layer thickness that is greater than a coherence length of external light.

### RELATED APPLICATIONS

The present application is a national stage entry according to 35 U.S.C. §371 of PCT application No.: PCT/EP2014/062708 filed on Jun. 17, 2014 which claims priority from German application No.: 10 2013 106 502.3 filed on Jun. 21, 2013, and is incorporated herein by reference in its entirety.

### TECHNICAL FIELD

Various embodiments relate to an optoelectronic component, to a method for producing an optoelectronic component, and to a mirror device.

### BACKGROUND

Conventional optoelectronic components, for example OLEDs, are usually constructed from a substrate, optically functional layers, for example organic functional layers, electrode layers, an encapsulation layer, for example a thin-film encapsulation layer (TFE), against action of moisture, and a cover, for example a cover plate. In many cases, a heat sink and/or a heat spreader, for example a metal plate or a metal film, are/is also laminated onto the cover glass. The cover plate serves as mechanical protection and as a further moisture barrier and, like the substrate, generally consists of solid glass. The cover glass is usually laminated onto the substrate over the whole area in the context of the production process. The encapsulation layer is formed between the cover plate and the substrate and generally extends over the entire substrate.

A conventional optoelectronic component can be formed in such a way that it acts in a specularly reflective fashion at least from one side. By way of example, a bottom emitting OLED (bottom emitter) may include a transparent substrate, a transparent first electrode arranged on the substrate, for example an anode, and a specularly reflective second electrode spaced apart from the first electrode, for example a cathode. Such an OLED can be used as a mirror, for example on account of its metallically lustrous appearance in the switched-off state (“off state”). By way of example, application as a vanity mirror in an automobile, as a bathroom mirror or as a handbag mirror is appropriate here. In these applications it may be intended that the OLED in the switched-on state is luminous in an optically active edge region and emits for example pleasant light having a high color rendering index (CRI), while a central area bordered by the edge region is optically passive and serves only as a mirror.

In conventional mirrors with OLEDs, the organic layers of the OLEDs can be applied on the substrate over the whole area, that is to say also on the passive, that is to say non-luminous and specularly reflective, area. By virtue of the fact that the organic layers usually have a thickness of only a few hundred nanometers, that is to say of the order of magnitude of the wavelengths of the spectral range of visible light, an optical cavity, a so-called microcavity, forms on account of a difference in the refractive indices between the material of the substrate and the organic assembly. In conjunction with the specularly reflective cathode, the incident ambient light interferes with the ambient light reflected from the cathode, wherein the optical cavity is spectrally selective, such that undesired and unattractive color casts of the mirror image occur when the mirror is viewed from different viewing angles.

In conventional mirror applications, OLEDs and mirrors can be produced separately and the finished components can be combined with one another. By way of example, the OLEDs can be produced separately and integrated into a mirror. In this case, the components (OLED and mirror) have to be produced separately from one another and then combined in a complex manner (milling holes in the mirror and introducing the OLED). This process can be very complex and cost-intensive. The OLED itself is still spectrally selective in the switched-off state. In these applications, therefore, the “illumination” function is separate from the “mirror” function.

A further possibility for realizing a specularly reflective area included in an OLED is to sever the organic layers and the cathode by means of a fine laser cut or to structure the anode by means of selective etching or laser steps before the organic layers are applied, such that the inner area of the OLED is no longer luminous. However, in this case, as already described above, the optically passive, specularly reflective inner region is covered by the organic layers, thus resulting in a pronounced viewing angle dependence of the mirror image.

### SUMMARY

In various embodiments, an optoelectronic component and/or a mirror device are/is provided which are/is formed in a simple fashion and/or which provide(s) a mirror and/or include(s) a luminaire, wherein the mirror provides a homogeneous mirror image over its entire specularly reflective area, in particular independently of the operating state and/or independently of the viewing angle.

In various embodiments, a method for producing an optoelectronic component is provided which makes it possible in a simple manner to provide a mirror and/or a luminaire by means of the optoelectronic component, wherein the mirror provides a homogeneous mirror image over its entire specularly reflective area, in particular independently of the operating state and/or independently of the viewing angle.

In various embodiments, an optoelectronic component is provided. The optoelectronic component includes a carrier, which is formed in a transparent fashion. An optoelectronic layer structure is formed over the carrier and includes a first electrode, which is formed in a transparent fashion, an optically functional layer structure, which is formed over the first electrode, and a second electrode, which is formed over the optically functional layer structure. A mirror region is formed on a side of the optically functional layer structure facing away from the carrier, said mirror region being formed in a specularly reflective fashion as viewed at least from the carrier. An intermediate layer is formed between the carrier and the mirror region and has an optical layer thickness that is greater than a coherence length of external light.

The optical layer thickness results from the wavelength of the incident light and the refractive index of the material of the intermediate layer. In the case of the optical layer thickness that is greater than the greatest coherence length of the spectral range of the external light, no formation of an optical cavity, for example a microcavity, occurs and the entire layer stack including the intermediate layer, the first electrode and the optically functional layer structure can be interpreted as optically incoherent. The microcavity of the optoelectronic component, for example of an OLED, is broken up. As a result, the intermediate layer brings about a cancellation of the spectral selectivity of the mirror image and of the dependence of the specular reflection on the viewing angle. Therefore, the optoelectronic component in the switched-off state appears as a perfect mirror. The optoelectronic component can be used as a mirror device for viewing a mirror image with an integrated luminous surface.

The intermediate layer can have for example the same or at least approximately the same refractive index as the first electrode, which includes ITO, for example, and the optically functional layer structure, which includes an organic functional layer structure, for example. Alternatively or additionally, the intermediate layer can have a negligible extinction coefficient.

The intermediate layer can be formed between the carrier, for example a glass substrate, and the optoelectronic layer structure. As an alternative thereto, the intermediate layer can be formed between the optically functional layer structure and the second electrode. In these two alternatives, the second electrode, for example the cathode, may be formed in a specularly reflective fashion and include or form the mirror region. By way of example, the second electrode may include a metallic material, for example a metal and/or a semimetal. The intermediate layer can then be formed in an electrically conductive fashion, for example. The intermediate layer can be formed for example by an electron transport layer and/or an electron injection layer, which can be doped and/or which is formed such that it is particularly thick compared with a conventional electron transport layer and/or electron injection layer.

Furthermore, the optoelectronic component may include a cover arranged above the second electrode. The second electrode can be formed in a transparent fashion and the cover may include the mirror region or the mirror region can be formed between the second electrode and the cover. The intermediate layer can be formed between the second electrode and the mirror region.

The external light is light that is not generated by the OLED. By way of example, the external light is visible light that is incident on the optoelectronic component 10 from outside. The external light can be for example natural light, for example sunlight, or artificial light, for example a lighting in a closed space, for example a bathroom or a vehicle, for example an interior lighting of an automobile, for example “ambient light”. Consequently, the layer thickness of the intermediate layer can depend on the later use environment.

In this application, the coherence length relates, in principle, to the coherence length in the medium. The coherence length of the incident light in the medium can be calculated by means of the following formula F1:

L=2*ln(2)*λ²/(Π*n*Δλ), (F1)

wherein λ is the wavelength of the incident light, n is the refractive index of the intermediate layer (n>1; for air n=1) and Δλ is the spectral width, for example the full width at half maximum of the incident light spectrum of the external light. Consequently, the coherence length is also determined by the spectral width of the spectrum. The wider the spectrum, the smaller the coherence length. The narrower the spectrum, the larger the coherence length. By way of example, the coherence length of natural light, for example of sunlight, is of the order of magnitude of the average wavelength for example at approximately 1 μm.

The layer thickness can then be calculated by means of the following formula F2:

D>L (F2)

wherein D is the layer thickness and L is the coherence length.

In various embodiments, the second electrode is formed in a specularly reflective fashion, and the mirror region is formed by the second electrode. The second electrode can be for example the cathode of the optoelectronic component. The second electrode may include for example a metallic material, for example a metal, a semimetal and/or a semiconductor. The second electrode may include for example aluminum, silver, magnesium or a mixture or an alloy including one or a plurality of these materials. By way of example, the second electrode may include AgMg. The fact that the second electrode is formed in a specularly reflective fashion contributes to the fact that the optoelectronic component can be formed simply and/or cost-effectively. By way of example, forming or arranging an additional mirror layer including the mirror region and/or a specularly reflective cover can be dispensed with.

In various embodiments, the second electrode is formed in a transparent fashion, and a mirror layer is formed above the second electrode, the mirror region being formed by said mirror layer.

In various embodiments, the optoelectronic layer structure includes at least one optically active region and at least one optically passive region. The optically active region can be for example a region in which, during the operation of the optoelectronic component, electromagnetic radiation is generated on account of a current flow or electromagnetic radiation is absorbed for the purpose of generating a current flow. Outside operation of the optoelectronic component, that is to say in the off state of the optoelectronic component, the optically active region can serve as a mirror, for example for viewing a mirror image. The optically passive region can also be referred to as optically inactive region. The optically passive region serves as a mirror, for example for viewing a mirror image, independently of the operating state of the optoelectronic component, that is to say in the on state and in the off state. During the operation of the optoelectronic component, therefore, a luminous surface of the mirror is arranged in the optically active region and a mirror surface of the mirror is arranged in the optically passive region.

In various embodiments, a first optically active region surrounds the optically passive region, and the optically passive region surrounds a second optically active region. By way of example, the first optically active region can extend around the passive region in a frame-shaped fashion and thus form a luminous frame around the mirror surface during operation. The second optically active region can form a luminous surface during operation in the mirror surface. The second optically active region can be formed for example in such a way that information is represented by the luminous surface in the mirror surface, for example a letter, a word and/or lettering and/or a graphic, for example an image or a logo.

In various embodiments, the optically active region is separated from the optically passive region on account of an interruption of at least one part of the optoelectronic layer structure during the transition from the active region to the passive region. By way of example, the optoelectronic component can firstly be produced independently of the optically active region and the optically passive region as a component that is active potentially over the whole area. Afterward, the interruption can be introduced in such a way that the optically functional layer structure in the optically passive region is no longer functional and is therefore only passive and specularly reflective. As an alternative thereto, the interruption can already be introduced during production of the optoelectronic component, for example by forming an optically passive layer instead of at least one part of the optoelectronic layer structure in the optically passive region in such a way that the optically functional layer structure in the optically passive region is no longer functional and is therefore only passive and specularly reflective.

In various embodiments, the optically active region is separated from the optically passive region on account of an interruption of the first and/or second electrode during the transition from the active region to the passive region. This makes it possible, in a simple manner, to suppress the functionality of the optically functional layer structure in the optically passive region.

In various embodiments, the optically active region is separated from the optically passive region on account of an interruption of the optically functional layer structure during the transition from the active region to the passive region. This makes it possible, in a simple manner, to impair the functionality of the optically functional layer structure in the optically passive region.

In various embodiments, an optically passive layer is formed in the optically passive region between the carrier and the mirror region instead of at least one part of the optoelectronic layer structure. This makes it possible, in a simple manner, to suppress the functionality of the optically functional layer structure in the optically passive region. By way of example, the optically passive layer can be formed in the optically passive region instead of the first electrode, instead of the second electrode and/or instead of the optically functional layer structure. The fact that the optically passive layer is optically passive means, in this context, that the optically passive layer is not suitable for generating electromagnetic radiation or for generating current or a voltage. The optically passive layer can be formed in a transparent fashion, for example.

In various embodiments, a method for producing an optoelectronic component, for example the optoelectronic component explained above, is provided. In the method, the carrier, which is formed in a transparent fashion, is provided. By way of example, the carrier is formed. The transparent first electrode of the optoelectronic layer structure is formed above the carrier. The optically functional layer structure of the optoelectronic layer structure is formed above the first electrode. The second electrode of the optoelectronic layer structure is formed above the optically functional layer structure. The mirror region is formed on the side of the optically functional layer structure facing away from the carrier, said mirror region being formed in a specularly reflective fashion as viewed at least from the carrier. The intermediate layer between the carrier and the mirror region is formed in such a way that the optical layer thickness of the intermediate layer is greater than the coherence length of the external light.

If the mirror region is formed by the second electrode, then the mirror region is formed together with the second electrode, that is to say simultaneously. In other words, the mirror region is then formed in the course of the process of forming the second electrode.

In various embodiments, an optoelectronic component is provided. The optoelectronic component includes a carrier, which is formed in a transparent fashion, and an optically active region and an optically passive region. An optoelectronic layer structure is formed in the optically active region. The optoelectronic layer structure includes: a first electrode, which is formed above the carrier and which is formed in a transparent fashion, an optically functional layer structure, which is formed above the first electrode, and a second electrode, which is formed above the optically functional layer structure. A mirror region is formed on a side of the optically functional layer structure facing away from the carrier, said mirror region being formed in a specularly reflective fashion as viewed at least from the carrier. A mirror layer is formed in the optically passive region above the carrier, said mirror layer being formed in a specularly reflective fashion as viewed at least from the carrier.

No optoelectronic layer structure is formed between the mirror layer and the carrier. The mirror layer can be formed for example directly on the carrier. The mirror layer can be formed for example in the optically passive region instead of the first electrode, or the mirror layer can be formed by the second electrode. By way of example, the optically active region can be formed in a manner corresponding to the optically active region explained above. In the optically passive region, the first electrode and the optically functional layer structure can be dispensed with, or the first electrode and/or the optically functional layer structure are/is formed as dummy layers, for example as non-functional layers, above the mirror layer. The mirror layer above the carrier without an optoelectronic layer structure therebetween has the effect that a perfect mirror can be formed in the optically passive region independently of the operating state of the optoelectronic component. It is only in the optically active region that the disadvantages described above can occur in the off state of the optoelectronic component. However, said disadvantages can be accepted depending on the intended application of the optoelectronic component, since the corresponding mirror device with mirror surface and luminous surface can be produced very simply and cost-effectively.

In various embodiments, an organic layer structure is formed in the optically passive region above the mirror layer. This can contribute to the simple and/or cost-effective production of the optoelectronic component since merely the mirror layer has to be structured and/or formed selectively above the carrier and afterward the optoelectronic layer structure can be formed in a simple manner in the whole area over the entire carrier with the mirror layer.

In various embodiments, the carrier extends integrally over the optically active region and the optically passive region. In other words, the optically active region and the optically passive region are constructed on a single carrier. The optoelectronic component, for example the mirror device with mirror surface and luminous surface, therefore need not be composed of individual parts, in particular optically active elements and optically passive elements, which are produced separately from one another, but rather can be produced in a closed, simple and/or cost-effective method.

In various embodiments, a method for producing an optoelectronic component, for example the optoelectronic component explained above, is provided. In this case, the transparent carrier is provided. The optically active region and the optically passive region are formed. An optoelectronic layer structure is formed in the optically active region by virtue of a transparent first electrode of the optoelectronic layer structure being formed above the carrier, an optically functional layer structure of the optoelectronic layer structure is formed above the first electrode, and a second electrode of the optoelectronic layer structure is formed above the optically functional layer structure. A mirror region is formed on a side of the optically functional layer structure facing away from the carrier, said mirror region being formed in a specularly reflective fashion as viewed at least from the carrier. In the optically passive region a mirror layer is formed above the carrier, said mirror layer being formed in a specularly reflective fashion as viewed at least from the carrier.

In particular, no optoelectronic layer structure is formed between the mirror layer and the carrier. The mirror layer can be formed for example directly on the carrier. The optoelectronic layer structure can be formed for example selectively in the optically active region. The optoelectronic layer structure can be formed for example in the optically active region by means of a printing process.

In various embodiments, a mirror device is provided, including a mirror surface for viewing a mirror image and a luminous surface for emitting light, for example the mirror device mentioned above. The mirror device includes the optoelectronic component. The mirror surface is formed by the optically passive region, and the luminous surface is formed by the optically active region. The mirror device can be used for example as a mirror, for example as a vanity or shaving mirror, for example in an automobile or a bathroom, or as a portable pocket mirror.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a conventional optoelectronic component;

FIG. 2 shows a plan view of a conventional optoelectronic component;

FIG. 3 shows a sectional illustration of the conventional optoelectronic component in accordance with FIG. 2;

FIG. 4 shows a plurality of diagrams which show the reflection of light incident into the conventional optoelectronic component for different viewing angles depending on the wavelength of the incident light;

FIG. 5 shows a sectional illustration of one embodiment of an optoelectronic component;

FIG. 6 shows a plurality of diagrams which show the reflection of light incident into the optoelectronic component in accordance with FIG. 5 for different viewing angles depending on the wavelength of the incident light;

FIG. 7 shows a sectional illustration of one embodiment of an optoelectronic component;

FIG. 8 shows a sectional illustration of one embodiment of an optoelectronic component;

FIG. 9 shows a sectional illustration of one embodiment of an optoelectronic component in a first state during a method for producing the optoelectronic component;

FIG. 10 shows a sectional illustration of one embodiment of an optoelectronic component in a second state during the method for producing the optoelectronic component;

FIG. 11 shows a sectional illustration of one embodiment of an optoelectronic component;

FIG. 12 shows a plan view of one embodiment of an optoelectronic component;

FIG. 13 shows a plan view of one embodiment of an optoelectronic component;

FIG. 14 shows a sectional illustration of a layer structure of one embodiment of an optoelectronic component.

### DETAILED DESCRIPTION

In the following detailed description, reference is made to the accompanying drawings, which form part of this description and show for illustration purposes specific embodiments in which the invention can be implemented. In this regard, direction terminology such as, for instance, “at the top”, “at the bottom”, “at the front”, “at the back”, “front”, “rear”, etc. is used with respect to the orientation of the figure(s) described. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present invention. It goes without saying that the features of the various embodiments described herein can be combined with one another, unless specifically indicated otherwise. Therefore, the following detailed description should not be interpreted in a restrictive sense, and the scope of protection of the present invention is defined by the appended claims.

In the context of this description, the terms “connected” and “coupled” are used to describe both a direct and an indirect connection and a direct or indirect coupling. In the figures, identical or similar elements are provided with identical reference signs, insofar as this is expedient.

An optoelectronic component can be an electromagnetic radiation emitting component or an electromagnetic radiation absorbing component. An electromagnetic radiation absorbing component can be a solar cell, for example. An electromagnetic radiation emitting component can for example be an electromagnetic radiation emitting semiconductor component and/or be formed as an electromagnetic radiation emitting diode, as an organic electromagnetic radiation emitting diode, as an electromagnetic radiation emitting transistor or as an organic electromagnetic radiation emitting transistor. The radiation can be for example light in the visible range, UV light and/or infrared light. In this context, the electromagnetic radiation emitting component can be formed for example as a light emitting diode (LED), as an organic light emitting diode (OLED), as a light emitting transistor or as an organic light emitting transistor. In various embodiments, the light emitting component can be part of an integrated circuit. Furthermore, a plurality of light emitting components can be provided, for example in a manner accommodated in a common housing.

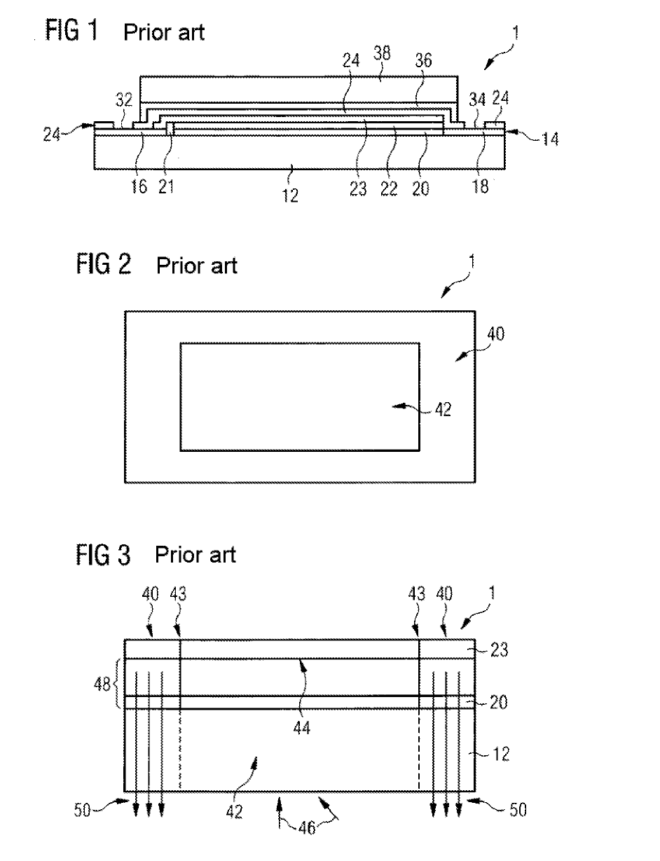

FIG. 1 shows a conventional optoelectronic component 1. The conventional optoelectronic component 1 includes a carrier 12, for example a substrate. An optoelectronic layer structure is formed on the carrier 12. The carrier 12 is formed in a transparent fashion. The fact that the carrier 12 or one of the layers explained in greater detail below is transparent or is formed in a transparent fashion means, for example, that the carrier 12 or the corresponding layer is transparent or transmissive at least to light in the visible spectral range.

The optoelectronic layer structure includes a first electrode layer 14, which includes a first contact section 16, a second contact section 18 and a first electrode 20. The second contact section 18 is electrically coupled to the first electrode 20 of the optoelectronic layer structure. The second contact section 18 and the first electrode 20 can be formed integrally, for example. The first electrode 20 is electrically insulated from the first contact section 16 by means of an electrical insulation barrier 21. An optically functional layer structure 22, for example an organic functional layer structure, of the optoelectronic layer structure is formed above the first electrode 20. The optically functional layer structure 22 may include for example one, two or more partial layers, as explained in greater detail further below with reference to FIG. 13. Above the organic functional layer structure 22, a second electrode 23 of the optoelectronic layer structure is formed, which is electrically coupled to the first contact section 16. The first contact section 16 and the second electrode can be formed integrally, for example. The first electrode 20 serves for example as an anode or a cathode of the optoelectronic layer structure. The second electrode 23 serves, correspondingly with respect to the first electrode, as a cathode or an anode of the optoelectronic layer structure.

Above the second electrode 23 and partly above the first contact section 16 and partly above the second contact section 18, an encapsulation layer 24 of the optoelectronic layer structure is formed, which encapsulates the optoelectronic layer structure. In the encapsulation layer 24, a first cutout of the encapsulation layer 24 is formed above the first contact section 16 and a second cutout of the encapsulation layer 24 is formed above the second contact section 18. A first contact region 32 is exposed in the first cutout of the encapsulation layer 24 and a second contact region 34 is exposed in the second cutout of the encapsulation layer 24. The first contact region 32 serves for electrically contacting the first contact section 16 and the second contact region 34 serves for electrically contacting the second contact section 18.

An adhesion medium layer 36 is formed above the encapsulation layer 24. A cover 38 is formed above the adhesion medium layer 36. The adhesion medium layer 36 serves for fixing the cover 38 to the encapsulation layer 24. The cover 38 serves for protecting the conventional optoelectronic component 1, for example against mechanical force actions, for example an impact or a blow, from outside. Furthermore, the cover 38 can serve for spreading and/or dissipating heat generated in the conventional optoelectronic component 1. By way of example, the glass of the cover 38 can serve as protection against external effects, and the metal layer of the cover 38 can serve for spreading and/or dissipating the heat that arises during the operation of the conventional optoelectronic component 1.

The adhesion medium layer 36 can be applied to the encapsulation layer 24 for example in a structured fashion. The fact that the adhesion medium layer 36 can be applied to the encapsulation layer 24 in a structured fashion can mean, for example, that the adhesion medium layer 36 already has a predefined structure directly upon application. By way of example, the adhesion medium layer 36 can be applied in a structured fashion by means of a dispensing or printing method.

The conventional optoelectronic component 1 can be singulated from a component assemblage, for example, by virtue of the carrier 12 being scribed and then broken along its outer edges illustrated laterally in FIG. 1, and by virtue of the cover 38 equally being scribed and then broken along its lateral outer edges illustrated in FIG. 1. In the course of this scribing and breaking, the encapsulation layer 24 is exposed above the contact regions 32, 34. Afterward, the first contact region 32 and the second contact region 34 can be exposed in a further method step, for example by means of an ablation process, for example by means of laser ablation, mechanical scraping or an etching method.

The second electrode 23 can be formed in a specularly reflective fashion, such that the conventional optoelectronic component 1, if it generates electromagnetic radiation, is formed as a bottom emitter. In this context, the conventional optoelectronic component 1 in the on state emits the electromagnetic radiation, for example visible light, in the direction toward the second electrode 23, from which it is reflected in the direction toward the carrier 12, and directly in the direction toward the carrier 12. The electromagnetic radiation is then emitted from the conventional optoelectronic component 1 toward the bottom in FIG. 1. In the off state, if the conventional optoelectronic component 1 is operated as a luminaire or if the conventional optoelectronic component 1 is operated as a solar cell, independently of the operating state, the conventional optoelectronic component 1 has, as viewed from the bottom in FIG. 1, a specularly reflective appearance on account of the specularly reflective second electrode 23 and can be used as a mirror.

FIG. 2 shows a plan view of a conventional optoelectronic component 1 formed as a mirror device having a mirror surface and having an integrated luminaire, in particular having an integrated luminous surface. The conventional optoelectronic component 1 includes an optically active region 40, for example a first optically active region 40, in particular an optically active edge region, and an optically passive region 42, in particular an optically passive inner region. The optically active region 40 borders the optically passive region 42. As an alternative thereto, the optically active region 40 may include one, two or more optically active partial regions, for example further optically active regions and/or second optically active regions, which can be separated from one another, for example, and/or which can be distributed over the area of the conventional optoelectronic component 1, for example. By way of example, the conventional optoelectronic component 1 may include a plurality of roundish, for example circular or oval, or polygonal, for example square or rectangular, partial regions, and/or the optically active partial regions can be arranged in a frame-shaped fashion, for example.

FIG. 3 shows a sectional illustration of the conventional optoelectronic component 1 in accordance with FIG. 2.

A layer structure of the conventional optoelectronic component 1 can for example largely correspond to the layer structure of the conventional optoelectronic component 1 explained with reference to FIG. 1. In the case of the conventional optoelectronic component 1 shown in FIG. 3, the contact sections 16, 18 and the contact regions 32, 34 and the insulator region 21 are not illustrated. These sections and regions can be formed outside the sectional edge shown in FIG. 3, for example, or the electrodes 20, 23 can be contacted for example via a side of the conventional optoelectronic component 1 on which the second electrode 23 is formed, or through the cover 38. The optically functional layer structure 22 and the first electrode 20 can have for example overall a thickness of 200 to 800 nm.

The second electrode 23 is formed in a specularly reflective fashion, such that ambient light which is incident into the conventional optoelectronic component 1 from the bottom is specularly reflected at a mirror region 44, which is formed by the second electrode 23 in this embodiment. As an alternative thereto, the second electrode 23 can also be formed in a transparent fashion and a mirror layer (not illustrated) can be formed on the second electrode 23, said mirror layer then including the mirror region 44. By way of example, the cover 38 may include or form the mirror layer.

In the case of the conventional optoelectronic component 1 shown in FIG. 3, the cover 38, the adhesion medium layer 36 and the encapsulation layer 24 are not depicted, for reasons of better illustratability. Optionally, these elements can be formed individually or jointly, however. By way of example, the encapsulation layer 24 can be formed, for example in a specularly reflective fashion, but the adhesion medium layer 36 and the cover 38 can be dispensed with.

The optoelectronic layer structure of the conventional optoelectronic component 1 is at least partially interrupted at transitions 43 from the optically active regions 40 to the optically inactive region 42. By way of example, the first electrode 20 and/or the second electrode 23 or the intervening optically functional layer structure 22 can be interrupted at the transitions 43 from the optically active region 40 to the optically inactive region 42. If the electrical contacting of the conventional optoelectronic component 1 then takes place exclusively in the optically active region 40, on account of the interruption at the transitions 43 the optoelectronic layer structure in the optically passive region 42 is not supplied with current and therefore is not luminous during the operation of the luminaire. In the case where the conventional optoelectronic component 1 is a solar cell, then the current generated in the optoelectronic layer structure is not transported away on account of the interruption. The transitions 43 can be produced for example by means of a selectively etched first and/or second electrode 20, 23 or by means of subsequent laser structuring of the first and/or second electrode 20, 23.

Independently of the operating state of the conventional optoelectronic component 1, that is to say in the on state and in the off state, light, for example the ambient light, is incident into the conventional optoelectronic component 1 from different viewing directions 46 and at correspondingly different viewing angles. In the on state, the conventional optoelectronic component 1 generates light in the optically active region 40 and emits the light in the direction toward the carrier 12 and in the direction toward the mirror region 44, the mirror region 44 reflecting the generated light toward the carrier 12, and emits the light from the carrier 12 into the surroundings. In the optically passive region 42, no light is generated, independently of the operating state. The conventional optoelectronic component 1 has a specularly reflective appearance in the optically passive region 42, independently of the operating state. The conventional optoelectronic component can thus be used as a mirror device having a mirror surface and an integrated luminous surface.

The part of the optoelectronic layer structure between a side of the first electrode 20 facing the carrier 12 and a first side of the second electrode 23 facing the carrier 12 forms an optical cavity 48, which can also be referred to as a microcavity. In the case of the conventional optoelectronic component 1, the optical layer thickness in a direction perpendicular to a surface of the carrier 12 on which the first electrode 20 is formed is in a range in which a coherence length of the external light which is incident into the conventional optoelectronic component 1 from the different viewing directions 46 also lies. On account of a difference in refractive index between the material of the carrier 12 and the material of the optoelectronic layer structure and on account of the mirror region 44, the incident ambient light interferes with the reflected ambient light. The interference is wavelength-selective and dependent on the viewing angle. This has the effect that an appearance of the conventional optoelectronic component 1 and/or a mirror image represented by means of the conventional optoelectronic component 1 render(s) colors with varying quality and to varying extents depending on the viewing direction 46. This leads to a distortion and/or unsharp representation of the appearance and/or mirror image and to a color cast.

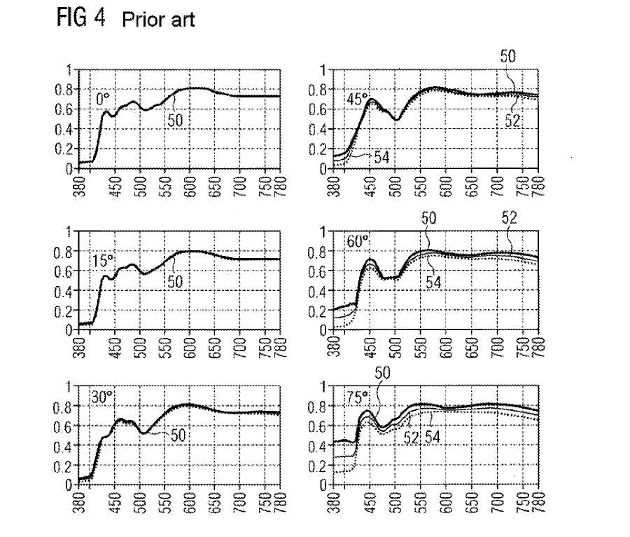

FIG. 4 shows a plurality of diagrams showing the reflection of the light incident on the conventional optoelectronic component depending on its wavelength at different viewing angles. The diagrams were recorded by means of the conventional optoelectronic component 1. The wavelengths of the incident light are plotted on the x-axes of the diagrams and the reflectivity is plotted on the y-axes. First curves 50 relate to the total reflection of transverse-electric and transverse-magnetic light waves, second curves 52 relate to the reflection of the transverse-electric light waves and third curves 54 relate to the reflection of the transverse-magnetic light waves.

FIG. 4 reveals that the reflectivity is greatly dependent on the wavelength of the incident light at all viewing angles. This means that at all viewing angles different colors are reflected to different extents, as a result of which a color cast and a color distortion of the mirror image arise at all viewing angles. Furthermore, the diagrams show that, particularly at relatively large viewing angles, for example at 45°, 60° or 75°, the reflectivity is additionally different in the case of the transverse-electric and transverse-magnetic light waves. By way of example, the reflectivity is relatively low in the blue and green spectral range. By way of example, the reflectivity dips at approximately 500 nm. Furthermore, an orange and/or red spectral range is relatively independent of the viewing angle. This has the effect that the mirror image acquires a different color cast depending on the viewing angle, which is perceived as negative and/or unattractive by a human observer.

FIG. 5 shows one embodiment of an optoelectronic component 10, which can for example largely correspond to the conventional optoelectronic component 1 explained above. The optoelectronic component 10 includes an intermediate layer 60. The intermediate layer 60 has an optical layer thickness that is greater than the coherence length of the incident light.

The incident, external light is visible light in this context. The visible light lies in a wavelength range of 350 nm to 850 nm, for example of 370 nm to 800 nm, for example of 400 to 750 nm. The optical layer thickness can be for example greater than the coherence length of the incident light in the medium. The optical layer thickness results from the quotient of the wavelength of the incident light and the refractive index of the intermediate layer 60. The coherence length of the light (in the medium for n not equal to 1) can be determined using the formula F1 mentioned above.

Furthermore, D>L holds true, that is to say that the optical layer thickness must be greater than the coherence length of the external, for example incident, light. The greater n is, the smaller the coherence length L in the medium becomes and the smaller the optical layer thickness D can become, and, in other words, the more wavelengths pass into the intermediate layer 60. By way of example, approximately L=1 μm can be assumed as the coherence length of visible light in air. For n=1.8, it can then be the case that D>L/n=555 nm. For n=1.5, for example, it can be the case that D>666 nm. If the exact coherence length and/or the constitution of the external light are/is not known, then the intermediate layer 60 can be formed with a particularly large layer thickness. By way of example, the layer thickness can then be D=1.5 μm.

The intermediate layer 60 can have for example the same refractive index or at least approximately the same refractive index as the optoelectronic layer structure, for example as the first electrode 20 and/or the optically functional layer structure 22. By way of example, the optoelectronic layer structure 22 and/or the first electrode 20 can have a refractive index in a range for example of 1.6 to 1.9, for example of 1.7 to 1.8. Accordingly, the intermediate layer 60 can have a refractive index in a range for example of 1.6 to 1.9 or of 1.7 to 1.8. The carrier 12 can have for example a refractive index of approximately 1.5 and a thickness of 0.2 to 2 mm.

The layer thickness of the intermediate layer 60 can then be greater than 1.5 μm, for example. In particular, for external light at approximately 555 nm and an assumed spectral width of 50 nm and a refractive index of n=1.7, the minimum thickness of 1.5 μm results for the intermediate layer 60. The external light is light that is not generated by the optoelectronic component 10. By way of example, the external light is light that is incident on the optoelectronic component 10 from outside. The external light can be for example natural light, for example sunlight, or artificial light, for example a lighting in a closed space, for example a bathroom or a vehicle, for example an interior lighting of an automobile, for example “ambient light”. Consequently, the layer thickness of the intermediate layer 60 can depend on the later use environment. By way of example, the layer thickness can be adapted to a vehicle interior lighting of a motor vehicle in which the optoelectronic component 10 is intended to be used. As an alternative thereto, the layer thickness can be adapted to a living space lighting of a space in which the optoelectronic component 10 is intended to be used. Furthermore, the layer thickness can be adapted to the sunlight. If the later use of the optoelectronic component 10 is not known or is intended to remain open at the time of production, then the layer thickness can be adapted to the sunlight, for example. The fact that the layer thickness is adapted to light, for example artificial or natural light, can mean, for example, that the layer thickness is adapted to the spectrum of the light and/or to the coherence length of the light.

The intermediate layer 60 may include for example a transparent lacquer with TiO₂ nanoparticles embedded therein. A size of the nanoparticles can be for example in a range for example of 1 nm to 100 nm, for example of 25 nm to 75 nm, for example approximately 50 nm, such that no scattering of the incident light and thus a milky appearance in the off state are brought about.

As a result of the introduction of the intermediate layer 60 having the same refractive index as the first electrode 20 and the optoelectronic layer structure, the microcavity 48 is canceled. The intermediate layer 60 with its specific optical layer thickness has the effect that the incident light interferes with itself only negligibly or not at all, with the result that the quality of the mirror image is no longer dependent on the color and/or the viewing angle. This has the effect that the entire optoelectronic component 10, that is to say in the optically active region 40 and in the optically passive region 42, can provide a homogeneous and viewing-angle-independent specular reflection in the off state.

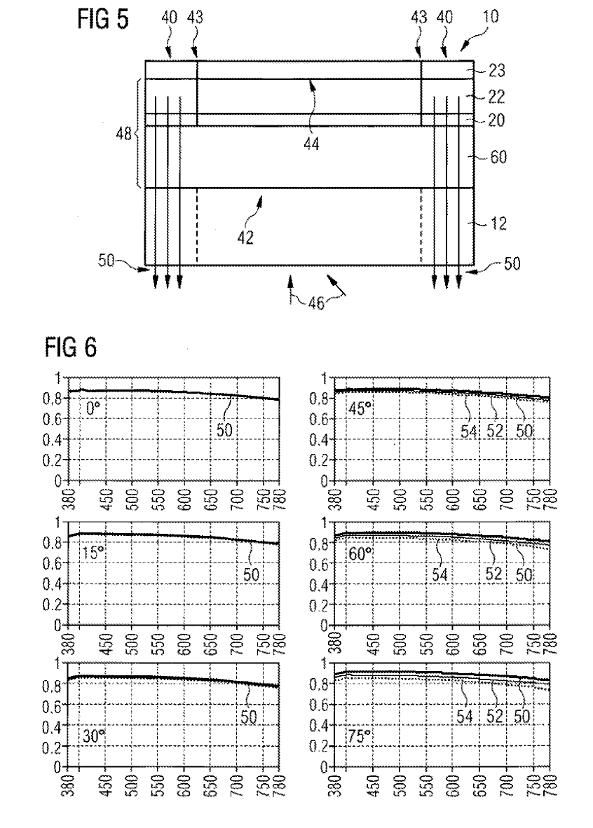

FIG. 6 shows a plurality of diagrams showing the reflection of the light incident on the optoelectronic component 10 depending on its wavelength at different viewing angles. The diagrams were recorded by means of the optoelectronic component 10 in accordance with FIG. 5. The wavelengths of the incident light are plotted on the x-axes of the diagrams and the reflectivity is plotted on the y-axes. The first curves 50 relate to the total reflection of transverse-electric and transverse-magnetic light waves, the second curves 52 relate to the reflection of the transverse-electric light waves and the third curves 54 relate to the reflection of the transverse-magnetic light waves.

FIG. 6 reveals that the reflectivity is relatively homogeneous over the entire wavelength range of the external light. Furthermore, the reflectivity is independent of the viewing angle. A small difference occurs only between the transverse-electric and transverse-magnetic light waves at large viewing angles, but said difference is only scarcely perceived or not perceived at all by the human eye. This has the effect that with the human eye at different viewing angles no color cast is discernible and the mirror image and/or the specular reflection are/is perceived as attractive specular reflection.

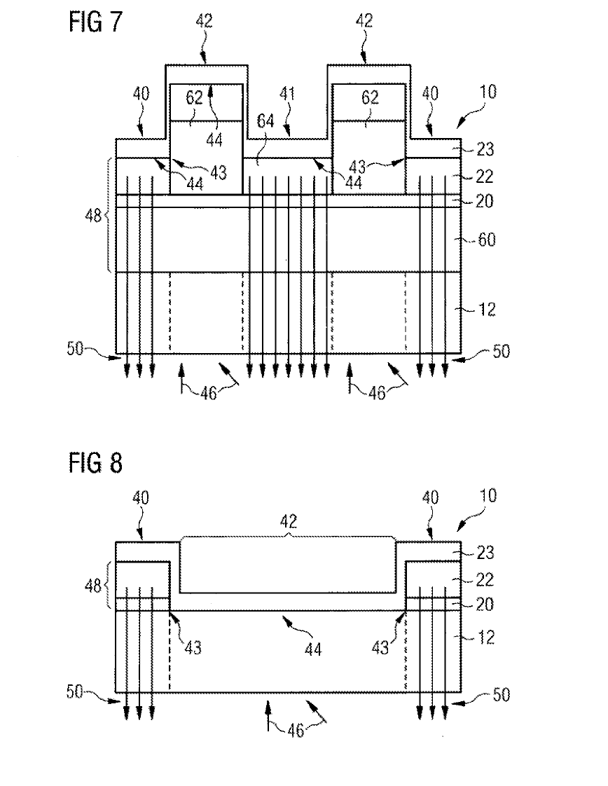

FIG. 7 shows one embodiment of the optoelectronic component 10, which can for example largely correspond to the optoelectronic component 10 explained with reference to FIG. 5. The optoelectronic component 10 includes, in particular, the intermediate layer 60 having the optical layer thickness explained above. Furthermore, the optoelectronic component 10 includes an optically passive layer 62 in the optically passive regions 42. The optically passive layer 62 brings about the transitions 43 toward the optically active regions 40, wherein the optically passive layer 62 in the optically passive region 42 replaces at least parts of the optoelectronic layer structure. By way of example, it is possible to form the optically passive material 62 in the optically passive region 42 instead of the optically functional layer structure 22 and/or instead of the second electrode 23.

A further optically active region 41 is formed between the optically passive regions 42. In this way, one, two or more further optically active regions 41 having virtually arbitrary form can be formed within the optically passive region 42. This can make it possible, for example, to represent one letter, a plurality of letters or lettering and/or a graphical representation, for example an image, a character, or a logo, luminously within the specularly reflective surface of the optoelectronic component 10.

The optically passive layer 62 may include or be formed by a transparent lacquer, for example. The lacquer can additionally contribute to the fact that the optoelectronic component 10 is not luminous in the optically passive region 42 in the on state.

FIG. 8 shows a sectional illustration of one embodiment of an optoelectronic component 10, which can for example largely correspond to one of the optoelectronic components 10 explained above. In particular, the active regions 40 of the optoelectronic component 10 can be formed in a manner corresponding to the active regions 40 of the optoelectronic component 10 explained above.

The optoelectronic component 10 includes no optically functional layer structure 22 and/or no first electrode in its optically passive region 42. In contrast thereto, a mirror layer is formed directly on the carrier 12, such that the mirror region 44 is formed at the interface between the mirror layer and the carrier 12. By way of example, the mirror layer can be formed by the second electrode 23, in particular by a spur of the second electrode 23.

The optoelectronic component 10 can be produced for example by the first electrode 20 and the optically functional layer structure 22 being selectively applied in the optically active region 40, for example by means of a printing method. Finally, the second electrode can then be formed over a large area above the optically active region 40 and the optically passive region 42, as a result of which the mirror layer having the mirror region 44 is formed. Consequently, no microcavity is formed in the optically passive region 42 and no unattractive mirror reflections are caused there. Consequently, a perfect mirror is formed in the optically passive region 42. However, a slight distortion and/or color distortion can occur when viewing a mirror image in the optoelectronic component in the edge region, for example in the optically active region 40. Since the mirror surface and the luminous surface in this embodiment can be formed simultaneously on one and the same carrier 12 in a production method, the optoelectronic component 10 can, however, be formed particularly simply and/or cost-effectively.

FIG. 9 shows a sectional illustration of one embodiment of an optoelectronic component 10 in a first state, for example during a method for producing the optoelectronic component 10. In the first state, a mirror layer 68 having the mirror region 44 is formed on the carrier 12. An etch stop 64, for example a protective lacquer, is formed on a part of the mirror layer 68. Afterward, the mirror layer 68 can be removed outside the etch stop 64, for example in a chemical and/or physical etching process.

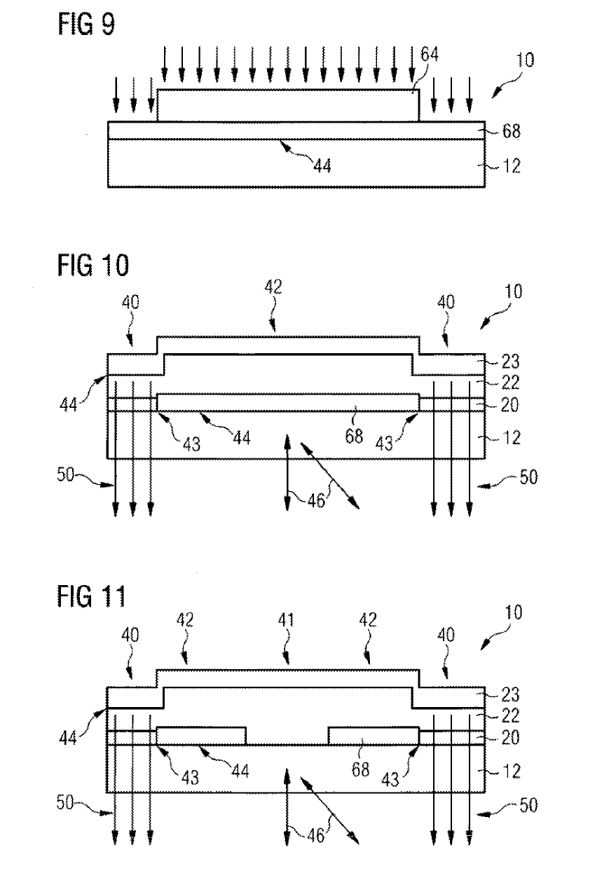

FIG. 10 shows the optoelectronic component 10 in accordance with FIG. 9 in a second state, for example during the method for producing the optoelectronic component 10. In the second state, the optoelectronic layer structure is formed above the entire carrier 12 and the mirror layer 68. On account of the mirror layer 68 in the inner region of the carrier 12, the optically functional layer structure 22 between the mirror layer 68 and the second electrode 22 is not active, however, for which reason only the optically functional layer structure 22 outside the mirror layer 68, in particular in the optically active region 40, generates light in the on state.

Consequently, no microcavity is formed in the optically passive region 42 and no unattractive mirror reflections are caused there. Consequently, a perfect mirror is formed in the optically passive region 42. In this embodiment, too, however, a color distortion dependent on the viewing angle or a color cast can occur in the optically active region 40, but this optoelectronic component 10, too, is producible simply and cost-effectively in a single method.

The first electrode 20 and the mirror layer 44 can be electrically conductively coupled to one another. Furthermore, the mirror layer 44 can be formed in an electrically conductive fashion. By way of example, the mirror layer 44 may include or be formed from electrically conductive material.

FIG. 11 shows a sectional illustration of one embodiment of an optoelectronic component 10, which can for example largely correspond to one of the optoelectronic components 10 explained above. The optoelectronic component 10 includes the further optically active region 41. The further optically active region 41 can be surrounded for example wholly or partly by the optically passive region 42. The optically active region 41 can be formed for example as a luminous island in the optically passive region 42 during operation. The further optically active region 41 can be formed for example by a cutout, for example a hole in the mirror layer 44. Current can be routed to the further optically active region 41 via the mirror layer 44, for example, provided that the latter is formed in an electrically conductive fashion. A step can be formed in the boundary region between the mirror layer 44 and the first electrode 20. In order that no short circuit can be caused by said step, said step can be overmolded and/or planarized with an electrically conductive and transparent passivation lacquer. Furthermore, the cutout in the mirror layer 44 can be filled by means of a filler, for example by means of a passivation lacquer. A transparent electrode for the operation of the further optically active region can be formed above the filler and below the optically functional layer structure.

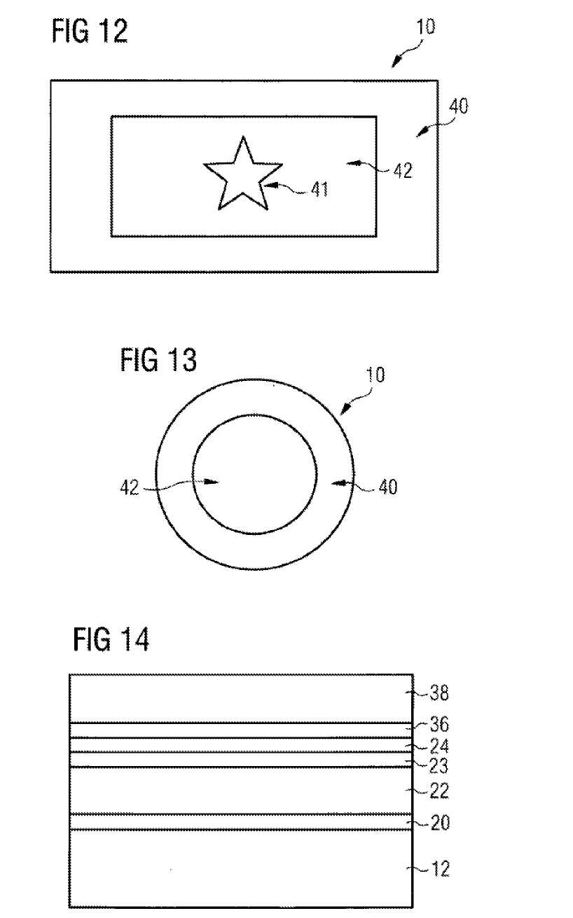

FIG. 12 shows a plan view of one embodiment of an optoelectronic component 10, which can be formed in sectional illustration for example in accordance with one of the optoelectronic components 10 explained above, for example in accordance with the optoelectronic component 10 shown in FIG. 7. The optically active region 40, in particular a first optically active region, is formed outside the optically passive region 42. Within the optically passive region 42, a further optically active region 41, in particular a second optically active region, is formed, which is formed in a star-shaped fashion in this embodiment. As an alternative thereto, however, the further optically active region 41 can also be formed differently and include for example letters, characters, letterings, graphics or a logo.

FIG. 13 shows one embodiment of an optoelectronic component 10, which can be formed in sectional illustration for example in accordance with one of the optoelectronic components 10 explained above. The optoelectronic component 10 is formed in a roundish fashion, in particular in a circular fashion, in plan view. As an alternative thereto, the optoelectronic component 10 can be formed in an oval fashion, for example.

FIG. 14 shows a detailed sectional illustration of a layer structure of one embodiment of an optoelectronic component, for example of the optoelectronic component 10 explained above, the optically passive region 42 not being illustrated in this detailed view. The optoelectronic component 10 is formed as a bottom emitter.

The optoelectronic component 10 includes the carrier 12 and an active region above the carrier 12. A first barrier layer (not illustrated), for example a first barrier thin-film layer, can be formed between the carrier 12 and the active region. The active region includes the first electrode 20, the organic functional layer structure 22 and the second electrode 23. The encapsulation layer 24 is formed above the active region. The encapsulation layer 24 can be formed as a second barrier layer, for example as a second barrier thin-film layer. The cover 38 is arranged above the active region and, if appropriate, above the encapsulation layer 24. The cover 38 can be arranged on the encapsulation layer 24 for example by means of an adhesion medium layer 36.

The active region is an electrically and/or optically active region. The active region is for example the region of the optoelectronic component 10 in which electric current for the operation of the optoelectronic component 10 flows and/or in which electromagnetic radiation is generated or absorbed.

The organic functional layer structure 22 may include one, two or more functional layer structure units and one, two or more intermediate layers between the layer structure units.

The carrier 12 is formed in a transparent fashion. The carrier 12 serves as a carrier element for electronic elements or layers, for example light emitting elements. The carrier 12 may include or be formed from, for example, glass, quartz, and/or a semiconductor material or any other suitable material. Furthermore, the carrier 12 may include or be formed from a plastics film or a laminate including one or including a plurality of plastics films. The plastic may include one or a plurality of polyolefins. Furthermore, the plastic may include polyvinyl chloride (PVC), polystyrene (PS), polyester and/or polycarbonate (PC), polyethylene terephthalate (PET), polyethersulfone (PES) and/or polyethylene naphthalate (PEN). The carrier 12 may include or be formed from a metal, for example copper, silver, gold, platinum, iron, for example a metal compound, for example steel. The carrier 12 can be formed as a metal film or a metal-coated film. The carrier 12 can be a part of a mirror structure or form the latter. The carrier 12 can have a mechanically rigid region and/or a mechanically flexible region or be formed in this way.

The first electrode 20 can be formed as an anode or as a cathode. The first electrode 20 can be formed as translucent or transparent. The first electrode 20 includes an electrically conductive material, for example metal and/or a transparent conductive oxide (TCO) or a layer stack of a plurality of layers including metals or TCOs. The first electrode 20 may include for example a layer stack of a combination of a layer of a metal on a layer of a TCO, or vice versa. One example is a silver layer applied on an indium tin oxide layer (ITO) (Ag on ITO) or ITO—Ag—ITO multilayers.

As metal, by way of example, use can be made of Ag, Pt, Au, Mg, Al, Ba, In, Ca, Sm or Li, and compounds, combinations or alloys of these materials.

Transparent conductive oxides are transparent conductive materials, for example metal oxides, such as, for example, zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, AlZnO, Zn₂SnO₄, CdSnO₃, ZnSnO₃, MgIn₂O₄, GaInO₃, Zn₂In₂O₅ or In₄Sn₃O₁₂, or mixtures of different transparent conductive oxides also belong to the group of TCOs.

As an alternative or in addition to the materials mentioned, the first electrode 20 may include: networks composed of metallic nanowires and nanoparticles, for example composed of Ag, networks composed of carbon nanotubes, graphene particles and graphene layers and/or networks composed of semiconducting nanowires. Alternatively or additionally, the first electrode 20 may include or be formed from one of the following structures: a network composed of metallic nanowires, for example composed of Ag, which are combined with conductive polymers, a network composed of carbon nanotubes which are combined with conductive polymers, and/or graphene layers and composites. Furthermore, the first electrode 20 may include electrically conductive polymers or transition metal oxides.

The first electrode 20 can have for example a layer thickness in a range of 10 nm to 500 nm, for example of less than 25 nm to 250 nm, for example of 50 nm to 100 nm.

The first electrode 20 can be coupled to a first electrical terminal, for example to the first contact section 16, to which a first electrical potential can be applied. The first electrical potential can be provided by an energy source (not illustrated), for example a current source or a voltage source. Alternatively, the first electrical potential can be applied to the carrier 12 and can be led to the first electrode 20 indirectly via the carrier 12. The first electrical potential can be for example the ground potential or some other predefined reference potential.

The organic functional layer structure 22 may include a hole injection layer, a whole transport layer, an emitter layer, an electron transport layer and/or an electron injection layer.

The hole injection layer can be formed on or above the first electrode 20. The hole injection layer may include or be formed from one or a plurality of the following materials: HAT-CN, Cu(I)pFBz, MoOₓ, WOₓ, VOₓ, ReOₓ, F4-TCNQ, NDP-2, NDP-9, Bi(III)pFBz, F16CuPc; NPB (N,N′-bis(naphthalen-1-yl)-N,N′-bis(phenyl)benzidine); beta-NPB N,N′-bis(naphthalen-2-yl)-N,N′-bis(phenyl)benzidine); TPD (N,N′-bis(3-methylphenyl)-N,N′-bis(phenyl)benzidine); spiro TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD N,N′-bis(3-methylphenyl)-N,N′-bis(phenyl)-9,9-dimethylfluorene); DMFL-NPB (N,N′-bis(napthalen-1-yl)-N,N′-bis(phenyl)-9,9-dimethylfluorene); DPFL-TPD (N,N′-bis(3-methylphenyl)-N,N′-bis(phenyl)-9,9-diphenylfluorene); DPFL-NPB (N,N′-bis(naphthalen-1-yl)-N,N′-bis(phenyl)-9,9-diphenylfluorene); spiro-TAD (2,2′,7,7′-tetrakis(n,n-diphenylamino)-9,9′-spirobifluorene); 9,9-bis[4-(N,N-bisphenyl-4-ylamino)phenyl]-9H-fluorene; 9,9-bis[4-(N,N-bisnapthalen-2-yl-amino)phenyl]-9H-fluorene; 9,9-bis[4-(N,N′-bisnaphthalen-2-yl-N,N′-bisphenylamino)phenyl]-9H-fluorene; N,N′-bis(phenanthren-9-yl)-N,N′-bis(phenyl)benzidine; 2,7-bis[N,N-bis(9,9-spirobifluoren-2-yl)amino)-9,9-spirobifluorene; 2,2′-bis[N,N-bis(biphenyl-4-yl)amino]9,9-spirobifluorene; 2,2′-bis(N,N-diphenylamino)9,9-spirobifluorene; di-[4-(N,N-ditolylamino)phenyl]cyclohexane; 2,2′,7,7′-tetra(N,N-ditolyl)aminospirobifluorene; and/or N,N,N′,N′-tetranaphthalen-2-ylbenzidine.

The hole injection layer can have a layer thickness in a range of approximately 10 nm to approximately 1000 nm, for example in a range of approximately 30 nm to approximately 300 nm, for example in a range of approximately 50 nm to approximately 200 nm.

The hole transport layer can be formed on or above the hole injection layer. The hole transport layer may include or be formed from one or a plurality of the following materials: NPB (N,N′-bis(naphthalen-1-yl)-N,N′-bis(phenyl)benzidine); beta-NPB N,N′-bis(naphthalen-2-yl)-N,N′-bis(phenyl)benzidine); TPD (N,N′-bis(3-methylphenyl)-N,N′-bis(phenyl)benzidine); spiro TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD N,N′-bis(3-methylphenyl)-N,N′-bis(phenyl)-9,9-dimethylfluorene); DMFL-NPB (N,N′-bis(naphthalen-1-yl)-N,N′-bis(phenyl)-9,9-dimethylfluorene); DPFL-TPD (N,N′-bis(3-methylphenyl)-N,N′-bis(phenyl)-9,9-diphenylfluorene); DPFL-NPB (N,N′-bis(naphthalen-1-yl)-N,N′-bis(phenyl)-9,9-diphenylfluorene); spiro-TAD (2,2′,7,7′-tetrakis(n,n-diphenylamino)-9,9′-spirobifluorene); 9,9-bis[4-(N,N-bisbiphenyl-4-yl-amino)phenyl]-9H-fluorene; 9,9-bis[4-(N,N′-bisnaphthalen-2-ylamino)phenyl]-9H-fluorene; 9,9-bis[4-(N,N′-bisnaphthalen-2-yl-N—N′-bisphenylamino)phenyl]-9H-fluorene; N,N-bis(phenanthren-9-yl)-N,N′-bis(phenyl)benzidine; 2,7-bis[N,N-bis(9,9-spirobifluoren-2-yl)amino]-9,9-spirobifluorene; 2,2′-bis[N,N-bis(biphenyl-4-yl)amino]9,9-spirobifluorene; 2,2′-bis(N,N-diphenylamino)9,9-spirobifluorene; di-[4-(N,N-ditolylamino)phenyl]cyclohexane; 2,2′,7,7′-tetra(N,N-ditolyl)aminospirobifluorene; and N,N,N′,N′-tetranaphthalen-2-yl-benzidine.

The hole transport layer can have a layer thickness in a range of approximately 5 nm to approximately 50 nm, for example in a range of approximately 10 nm to approximately 30 nm, for example approximately 20 nm.

The one or a plurality of emitter layers, for example including fluorescent and/or phosphorescent emitters, can be formed on or above the hole transport layer. The emitter layer may include organic polymers, organic oligomers, organic monomers, organic small, non-polymer molecules (“small molecules”) or a combination of these materials. The emitter layer may include or be formed from one or a plurality of the following materials: organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FIrPic (bis(3,5-difluoro-2-(2-pyridyl)phenyl(2-carboxypyridyl)iridium III), green phosphorescent Ir(ppy)₃ (tris(2-phenylpyridine)iridium III), red phosphorescent Ru (dtb-bpy)3*2(PF₆) (tris[4,4′-di-tert-butyl-(2,2′)-bipyridine]-ruthenium(III) complex) and blue fluorescent DPAVBi (4,4-bis[4-(di-p-tolylamino)styryl]biphenyl), green fluorescent TTPA (9,10-bis[N,N-di(p-tolyl)amino]-anthracene) and red fluorescent DCM2 (4-dicyanomethylene)-2-methyl-6-julolidyl-9-enyl-4H-pyran) as non-polymeric emitters. Such non-polymeric emitters can be deposited for example by means of thermal evaporation. Furthermore, polymer emitters can be used which can be deposited for example by means of a wet-chemical method, such as, for example, a spincoating method. The emitter materials can be embedded in a suitable manner in a matrix material, for example a technical ceramic or a polymer, for example an epoxy; or a silicone.

The first emitter layer can have a layer thickness in a range of approximately 5 nm to approximately 50 nm, for example in a range of approximately 10 nm to approximately 30 nm, for example approximately 20 nm.

The emitter layer may include emitter materials that emit in one color or in different colors (for example blue and yellow or blue, green and red). Alternatively, the emitter layer may include a plurality of partial layers which emit light of different colors. By means of mixing the different colors, the emission of light having a white color impression can result. Alternatively, provision can also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary radiation and secondary radiation.

The electron transport layer can be formed, for example deposited, on or above the emitter layer. The electron transport layer may include or be formed from one or a plurality of the following materials: NET-18; 2,2′,2″-(1,3,5-benzinetriyl)tris(1-phenyl-1-H-benzimidazole); 2-(4-biphenylyl)-5-(4-tert-butylphenyl)-1,3,4-oxadizole, 2,9-dimethyl-4,7-diphenyl-1,10-phenanthroline (BCP); 8-hydroxyquinolinolato lithium; 4-(naphthalen-1-yl)-3,5-diphenyl-4H-1,2,4-triazole; 1,3-bis[2-(2,2′-bipyridin-6-yl)-1,3,4-oxadiazo-5-yl]benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis[5-(biphenyl-4-yl)-1,3,4-oxadiazo-2-yl]-2,2′-bipyridyl; 2-phenyl-9,10-di(naphthalen-2-yl)anthracene; 2,7-bis[2-(2,2′-bipyridin-6-yl)-1,3,4-oxadiazo-5-yl]-9,9-dimethylfluorene; 1,3-bis[2-(4-tert-butylphenyl)-1,3,4-oxadiazo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-naphthalen-2-yl)phenyl)-1H-imidazo[4,5-f][1,10]phenanthroline; phenyl-dipyrenylphosphine oxide; naphthalenetetracarboxylic dianhydride or the imides thereof; perylenetetracarboxylic dianhydride or the imides thereof; and substances based on silols including a silacyclopentadiene unit.

The electron transport layer can have a layer thickness in a range of approximately 5 nm to approximately 50 nm, for example in a range of approximately 10 nm to approximately 30 nm, for example approximately 20 nm.

The electron injection layer can be formed on or above the electron transport layer. The electron injection layer may include or be formed from one or a plurality of the following materials: NDN-26, MgAg, Cs₂CO₃, Cs₃PO₄, Na, Ca, K, Mg, Cs, Li, LiF; 2,2′,2″-(1,3,5-benzinetriyl)tris(1-phenyl-1-H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxyquinolinolato lithium, 4-(naphthalen-1-yl)-3,5-diphenyl-4H-1,2,4-triazole; 1,3-bis[2-(2,2′-bipyridin-6-yl)-1,3,4-oxadiazo-5-yl)benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis(5-(biphenyl-4-yl)-1,3,4-oxadiazo-2-yl]-2,2′-bipyridyl; 2-phenyl-9,10-di(naphthalen-2-yl)anthracene; 2,7-bis[2-(2,2′-bipyridin-6-yl)-1,3,4-oxadiazo-5-yl]-9,9-dimethylfluorene; 1,3-bis[2-(4-tert-butylphenyl)-1,3,4-oxadiazo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f][1,10]phenanthroline; phenyldipyrenylphosphine oxide; naphthalenetetracarboxylic dianhydride or the imides thereof; perylenetetracarboxylic dianhydride or the imides thereof; and substances based on silols including a silacyclopentadiene unit.

The electron injection layer can have a layer thickness in a range of approximately 5 nm to approximately 200 nm inclusive, for example in a range of approximately 20 nm to approximately 50 nm, for example approximately 30 nm. If the electron injection layer is used as an intermediate layer 60, then its optical layer thickness can be chosen depending on the external light and can be chosen for example to be greater than the coherence length of the external light in the electron injection layer.

In the case of an organic functional layer structure 22 including two or more organic functional layer structural units, corresponding intermediate layers can be formed between the organic functional layer structure units. The organic functional layer structure units can be formed in each case individually per se in accordance with a configuration of the organic functional layer structure 22 explained above. The intermediate layer can be formed as an intermediate electrode. The intermediate electrode can be electrically connected to an external voltage source.

The external voltage source can provide a third electrical potential, for example, at the intermediate electrode. However, the intermediate electrode can also have no external electrical connection, for example by the intermediate electrode having a floating electrical potential.

The organic functional layer structure unit can have for example a layer thickness of a maximum of approximately 3 μm, for example a layer thickness of a maximum of approximately 1 μm, for example a layer thickness of a maximum of approximately 300 nm.

The optoelectronic component 10 may optionally include further functional layers, for example arranged on or above the one or the plurality of emitter layers or on or above the electron transport layer. The further functional layers can be for example internal or external coupling-in/coupling-out structures that can further improve the functionality and thus the efficiency of the optoelectronic component 10.

The second electrode 23 can be formed in accordance with one of the configurations of the first electrode 20, wherein the first electrode 20 and the second electrode 23 can be formed identically or differently. The second electrode 23 can be formed in a transparent fashion or in a specularly reflective fashion. The second electrode 23 can be formed as an anode or as a cathode. The second electrode 23 can have a second electrical terminal, to which a second electrical potential can be applied. The second electrical potential can be provided by the same energy source as, or a different energy source than, the first electrical potential. The second electrical potential can be different than the first electrical potential. The second electrical potential can have for example a value such that the difference with respect to the first electrical potential has a value in a range of approximately 1.5 V to approximately 20 V, for example a value in a range of approximately 2.5 V to approximately 15 V, for example a value in a range of approximately 3 V to approximately 12 V.

The encapsulation layer 24 can also be referred to as thin-film encapsulation. The encapsulation layer 24 can be formed as a specularly reflective, translucent or transparent layer. The encapsulation layer 24 forms a barrier with respect to chemical contaminants and/or atmospheric substances, in particular with respect to water (moisture) and oxygen. In other words, the encapsulation layer 24 is formed in such a way that substances that can damage the optoelectronic component, for example water, oxygen or solvent, cannot penetrate through said encapsulation layer, or at most very small proportions of said substances can penetrate through said encapsulation layer. The encapsulation layer 24 can be formed as an individual layer, a layer stack or a layer structure.

The encapsulation layer 24 may include or be formed from: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, poly(p-phenylene terephthalamide), nylon 66, and mixtures and alloys thereof.

The encapsulation layer 24 can have a layer thickness of approximately 0.1 nm (1 atomic layer) to approximately 1000 nm, for example a layer thickness of approximately 10 nm to approximately 100 nm, for example approximately 40 nm. The encapsulation layer 24 may include a high refractive index material, for example one or a plurality of material(s) having a high refractive index, for example having a refractive index of at least 2.

If appropriate, the first barrier layer can be formed on the carrier 12 in a manner corresponding to a configuration of the encapsulation layer 24.

The encapsulation layer 24 can be formed for example by means of a suitable deposition method, e.g. by means of an atomic layer deposition (ALD) method, e.g. a plasma enhanced atomic layer deposition (PEALD) method or a plasmaless atomic layer deposition (PLALD) method, or by means of a chemical vapor deposition (CVD) method, e.g. a plasma enhanced chemical vapor deposition (PECVD) method or a plasmaless chemical vapor deposition (PLCVD) method, or alternatively by means of other suitable deposition methods.

If appropriate, a coupling-in or -out layer can be formed for example as an external film (not illustrated) on the carrier 12 or as an internal coupling-out layer (not illustrated) in the layer cross section of the optoelectronic component 10. The coupling-in/-out layer may include a matrix and scattering centers distributed therein, wherein the average refractive index of the coupling-in/-out layer is greater than the average refractive index of the layer from which the electromagnetic radiation is provided. Furthermore, in addition, one or a plurality of antireflection layers can be formed.

The adhesion medium layer 36 may include for example an adhesion medium, for example adhesive, for example a lamination adhesive, lacquer and/or a resin, by means of which the cover 38 is arranged, for example adhesively bonded, for example on the encapsulation layer 24. The adhesion medium layer 36 can be formed in a specularly reflective fashion, in a transparent fashion or in a translucent fashion. The adhesion medium layer 36 may include for example particles which scatter electromagnetic radiation, for example light-scattering particles. As a result, the adhesion medium layer 36 can act as a scattering layer and lead to an improvement in the color angle distortion and the coupling-out efficiency.

The light-scattering particles provided can be dielectric scattering particles, for example, composed of a metal oxide, for example, silicon oxide (SiO₂), zinc oxide (ZnO), zirconium oxide (ZrO₂), indium tin oxide (ITO) or indium zinc oxide (IZO), gallium oxide (Ga₂Ox), aluminum oxide, or titanium oxide. Other particles may also be suitable provided that they have a refractive index that is different than the effective refractive index of the matrix of the adhesion medium layer 36, for example air bubbles, acrylate, or hollow glass beads. Furthermore, by way of example, metallic nanoparticles, metals such as gold, silver, iron nanoparticles, or the like can be provided as light-scattering particles.

The adhesion medium layer 36 can have a layer thickness of greater than 1 μm, for example a layer thickness of a plurality of μm. In various embodiments, the adhesive can be a lamination adhesive.

The adhesion medium layer 36 can have a refractive index that is less than the refractive index of the cover 38. The adhesion medium layer 36 can have for example a low refractive index adhesive such as, for example, an acrylate having a refractive index of approximately 1.3. However, the adhesion medium layer 36 may also include a high refractive index adhesive which for example includes high refractive index, non-scattering particles and has a layer-thickness-averaged refractive index that approximately corresponds to the average refractive index of the organic functional layer structure 22, for example in a range of approximately 1.7 to approximately 2.0.

A so-called getter layer or getter structure, i.e. a laterally structured getter layer, can be arranged (not illustrated) on or above the active region. The getter layer can be formed as translucent, transparent or opaque. The getter layer may include or be formed from a material that absorbs and binds substances that are harmful to the active region. A getter layer may include or be formed from a zeolite derivative, for example. The getter layer can have a layer thickness of greater than approximately 1 μm, for example a layer thickness of a plurality of μm. In various embodiments, the getter layer may include a lamination adhesive or be embedded in the adhesion medium layer 36.

The cover 38 includes glass and/or metal, for example. The cover 38 can be formed for example by a glass cover, a metal film and/or a sealed plastics film cover. By way of example, the cover 38 can be formed substantially from glass and include a thin metal layer, for example a metal film on the glass body. The cover 38 can be formed in a specularly reflective fashion. The cover 38 can be arranged on the encapsulation layer 24 or the active region for example by means of frit bonding (glass frit bonding/glass soldering/seal glass bonding) by means of a conventional glass solder in the geometrical edge regions of the organic optoelectronic component 10. The cover 38 can have for example a refractive index (for example at a wavelength of 633 nm) of 1.55.

The invention is not restricted to the embodiments specified. By way of example, in all the embodiments, the adhesion medium layer 36 and/or the cover 38 and/or the encapsulation layer 24 can be formed above the second electrode 23. Furthermore, in all the embodiments, the optically active regions 40 and the optically passive regions 42 can be formed such that letters, characters and/or graphics can be represented in plan view by means of the optically active regions 40 and/or the optically passive regions 42.

Furthermore, all the embodiments can be formed exclusively with an optically active region 40 and without an optically inactive region 42. If the optoelectronic component 10 generates electromagnetic radiation, then it can be used exclusively as a luminaire in the on state and exclusively as a mirror in the off state. If the optoelectronic component 10 absorbs electromagnetic radiation in order to generate current, then it can be used as a mirror over the whole area independently of the operating state, that is to say in the on state and in the off state.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An optoelectronic component, comprising:
a carrier, which is formed in a transparent fashion,
an optoelectronic layer structure comprising a first electrode, which is formed above the carrier and which is formed in a transparent fashion, an optically functional layer structure, which is formed above the first electrode, and a second electrode, which is formed above the optically functional layer structure, wherein a mirror region is formed on a side of the optically functional layer structure facing away from the carrier, said mirror region being formed in a specularly reflective fashion as viewed at least from the carrier, and
an intermediate layer, which is formed between the carrier and the mirror region and which has an optical layer thickness that is greater than a coherence length of external light.

2. The optoelectronic component as claimed in claim 1, wherein the second electrode is formed in a specularly reflective fashion, and wherein the mirror region is formed by the second electrode.

3. The optoelectronic component as claimed in claim 1, wherein the second electrode is formed in a transparent fashion, and wherein a mirror layer is formed above the second electrode, the mirror region being formed by said mirror layer.

4. The optoelectronic component as claimed in claim 1, wherein the optoelectronic layer structure comprises at least one optically active region and at least one optically passive region.

5. The optoelectronic component as claimed in claim 4, wherein the optically active region surrounds the optically passive region, and wherein the optically passive region surrounds a further optically active region.

6. The optoelectronic component as claimed in claim 4, wherein the optically active region is separated from the optically passive region on account of an interruption of at least one part of the optoelectronic layer structure during the transition from the active region to the passive region.

7. The optoelectronic component as claimed in claim 6, wherein the optically active region is separated from the optically passive region on account of an interruption of the first and/or second electrode during the transition from the active region to the passive region.

8. The optoelectronic component as claimed in claim 4, wherein the optically active region is separated from the optically passive region on account of an interruption of the optically functional layer structure during the transition from the active region to the passive region.

9. The optoelectronic component as claimed in claim 4, wherein an optically passive layer is formed in the optically passive region between the carrier and the mirror region instead of at least one part of the optoelectronic layer structure.

10. A method for producing an optoelectronic component, the method comprising:
providing a carrier, which is formed in a transparent fashion,
forming a transparent first electrode of an optoelectronic layer structure above the carrier,
forming an optically functional layer structure of the optoelectronic layer structure above the first electrode,
forming a second electrode of the optoelectronic layer structure above the optically functional layer structure, wherein a mirror region is formed on a side of the optically functional layer structure facing away from the carrier, said mirror region being formed in a specularly reflective fashion as viewed at least from the carrier, and
forming an intermediate layer between the carrier and the mirror region in such a way that an optical layer thickness of the intermediate layer is greater than a coherence length of external light.

11. An optoelectronic component, comprising:
a carrier, which is formed in a transparent fashion,
an optically active region and an optically passive region,
an optoelectronic layer structure, which is formed in the optically active region, comprising a first electrode, which is formed above the carrier and which is formed in a transparent fashion, an optically functional layer structure, which is formed above the first electrode, and a second electrode, which is formed above the optically functional layer structure, wherein a mirror region is formed on a side of the optically functional layer structure facing away from the carrier, said mirror region being formed in a specularly reflective fashion as viewed at least from the carrier, and
a mirror layer, which is formed in the optically passive region above the carrier and which is formed in a specularly reflective fashion as viewed at least from the carrier.

12. The optoelectronic component as claimed in claim 11, wherein an organic layer structure is formed in the optically passive region above the mirror layer.

13. The optoelectronic component as claimed in claim 11, wherein the carrier extends integrally over the optically active region and the optically passive region.

14. (canceled)

15. (canceled)
